(19) United States
(12) Patent Application Publication
(10) Pub. No.: US 2012/0145209 A1
(43) Pub. Date: Jun. 14, 2012

(54) THERMOELECTRIC ELEMENT AND THERMOELECTRIC MODULE INCLUDING THE SAME

(75) Inventors: Yongsuk KIM, Gyeonggi-do (KR); Sungho Lee, Gyeonggi-do (KR); Jeongho Yoon, Gyeonggi-do (KR); Taekon Koo, Seoul (KR); Donghyeok Choi, Gyeonggi-do (KR)

(73) Assignee: SAMSUNG ELECTRO-MECHANICS CO., LTD.

(21) Appl. No.: 13/212,796

(22) Filed: Aug. 18, 2011

(30) Foreign Application Priority Data
Dec. 9, 2010 (KR) 10-2010-0125792

(51) Int. Cl. H01L 35/04

(52) U.S. Cl. 136/200

(57) ABSTRACT

Disclosed herein are a thermoelectric element and a thermoelectric module including the same. The thermoelectric element is manufactured by differently setting diameter, density, and flatness, or laminating a plurality of sheets formed by mixing of metal or non-metal materials. Thus, thermoelectric figure of merit is improved in the thermoelectric module. Also, thermoelectric figure of merit, reliability, and efficiency of manufacturing process are improved in the thermoelectric module.

### CROSS REFERENCE(S) TO RELATED APPLICATIONS

This application claims the benefit under 35 U.S.C. Section 119 of Korean Patent Application Serial No. 10-2010-0125792, entitled “Thermoelectric Element and Thermoelectric Module Including The Same” filed on Dec. 9, 2010, which is hereby incorporated by reference in its entirety into this application.

### BACKGROUND OF THE INVENTION

1. Technical Field

The present invention relates to a thermoelectric element and a thermoelectric module including the same, and more particularly, to a thermoelectric element and a thermoelectric module capable of improving thermoelectric figure of merits, and a thermoelectric module capable of improving the reliability and the efficiency of a manufacturing process.

2. Description of the Related Art

Due to the rapid increase in the use of fossil fuel energy, which has caused global warming and energy depletion, the development of renewable energy has been actively advanced over the world.

In addition to the development of renewable energy, many studies are being conducted in regard to a thermoelectric module capable of utilizing energy efficiently.

Herein, the thermoelectric module may be used as a generator utilizing Seebeck effect in which electromotive force is generated when giving temperature difference between both ends of a thermoelectric element, or a cooling and heating device using Peltier effect in which one end radiates heat and the other end absorbs heat when applying direct current to the thermoelectric element. As electronic components become miniaturized, highly power-consumed, highly integrated, and slimmed along with remarkable growth of IT industries, it is necessary to cool various electronic devices like CPUs, etc., efficiently. In this situation, thermoelectric elements are expected to be variously applicable in the future because it has no noise and high cooling efficiency and it is capable of realizing local cooling and employing eco-friendly methods.

The thermoelectric module using such the thermoelectric elements may include upper and lower electrodes, and thermoelectric elements disposed between the upper and lower electrodes. Herein, substrates for supporting the thermoelectric elements are disposed on upper surfaces of the upper and lower electrodes, respectively. At this time, an alumina substrate having excellent electric insulating property is used for the substrates.

Meanwhile, the existing thermoelectric materials are mainly manufactured by mechanical alloying where metal raw materials are mixed at a constant composition ratio. That is, basic processes such as initial dissolving, crushing and sintering are used for bulk type thermoelectric elements, into which dopants are injected to manufacture a P-type semiconductor and a N-type semiconductor.

Also, those of ordinary skill in the art tend to focus on development, such as micronization of thermoelectric power particles and improvement of sintering density, in order to enhance the thermoelectric performance.

It has been focused on improving the thermoelectric figure of merit, zT, by utilizing superlattices or thermoelectric thin films low dimensionalized through various deposition methods in a thin film process, but remarkable success has not been shown so far. Therefore, technique development for improving the thermoelectric figure of merit is needed.

Meanwhile, the thermoelectric module includes a N-type semiconductor, a P-type semiconductor, metal electrodes of connecting between the two semiconductors, and ceramic substrates, and these constitute the minimum unit, which is referred to as a single module.

In order to use the single module as a cooling or generating power element, it is necessary to generate charges in the N-type and P-type semiconductors and then connect respective terminals to circuit through electrodes. Accordingly, in order to increase the efficiency of the single module, it is necessary to optimize the efficiency of respective parts constituting the module and the mutual efficiency between the respective parts in designing the single module.

However, as low conversion efficiency is required for the single module and high conversion efficiency is required in a field where the thermoelectric module is applicable, there is a rising interest on a complex module using several single modules.

The existing complex module has been manufactured by repeatedly connecting single modules each having P-N constitution in series according to conditions of use. Respective single modules are connected to each other by metal electrodes, and the metal electrodes are connected to ceramic substrates. Since the respective single modules are designed to be in parallel with each other from a heat source, a temperature gradient of semiconductor materials itself from the heat source is the same as that of the single modules. This existing serial type module structure has problems with respect to short circuits and fatal disadvantages in that the entire complex module dose not operate if any one of single modules is broken. Also, this serial type module has a high level of dependence on voltage.

### SUMMARY OF THE INVENTION

An object of the present invention is to provide a thermoelectric element capable of improving the thermoelectric figure of merits.

Another object of the present invention is to provide a thermoelectric module capable of improving the thermoelectric figure of merits and a thermoelectric module capable of improving the reliability and the manufacturing efficiency.

According to an exemplary embodiment of the present invention, there is provided a thermoelectric element formed by laminating a plurality of semiconductor layers. The semiconductor layers are, respectively, formed of at least two kinds of thermoelectric semiconductor materials which are different from each other in at least one of diameter, density and flatness.

According to another exemplary embodiment of the present invention, there is provided a thermoelectric element, including: first semiconductor layers formed of thermoelectric semiconductor materials; and second semiconductor layers formed of thermoelectric semiconductor materials which are different from the materials forming the first semiconductor layers in at least one of diameter, density and flatness.

Preferably, the first semiconductor layers and the second semiconductor layers are alternately laminated.

The first semiconductor layers and the second semiconductor layers may be alternately laminated to constitute a structure of at least three layers.

Preferably, the diameter of the materials forming the second semiconductor layers may be more than 1.5 times the diameter of the materials forming the first semiconductor layers.

Preferably, the diameter of the materials forming the first semiconductor layers may be about 10 nm to about 900 μm.

The density of the second semiconductor layers may be more than 1.5 times the density of the first semiconductor layers to distinguish the layers.

The rate between minor axis/major axis ratio of the materials forming the first semiconductor layers and minor axis/major axis ratio of the materials forming the second semiconductor layers may be in the range of 1:0.1 to 0.9, to distinguish the layers.

The diameter of the materials forming the first semiconductor layers may be divided into at least two kinds of values.

The diameter of the materials forming the second semiconductor layers may be divided into at least two kinds of values.

According to another exemplary embodiment of the present invention, there is provided a thermoelectric element, including: first thermoelectric layers formed of thermoelectric semiconductor materials; and second thermoelectric layers each formed by combining a region formed of thermoelectric semiconductor materials and a region formed of metal materials.

Preferably, the first thermoelectric layers and the second thermoelectric layers may be alternately laminated.

Preferably, the first thermoelectric layers and the second thermoelectric layers may be alternately laminated to constitute a structure of at least three layers.

Preferably, the region formed of the thermoelectric semiconductor materials and the region formed of the metal materials may be positioned differently in each of the second thermoelectric layers whenever the second thermoelectric layers are disposed in different layer levels.

Preferably, the diameter of the thermoelectric semiconductor materials forming the first thermoelectric layers may be different from the diameter of the thermoelectric semiconductor materials forming the second thermoelectric layers.

Preferably, the diameter of the materials forming the first semiconductor layers may be divided into at least two kinds of values.

Preferably, the diameter of the materials forming the second semiconductor layers may be divided into at least two kinds of values.

According to another exemplary embodiment of the present invention, there is provided a thermoelectric element, including: semiconductor layers formed of thermoelectric semiconductor material; and complex semiconductor layers each formed by mixing thermoelectric semiconductor materials having a different diameter from the materials forming the semiconductor layers and non-semiconductor materials.

The diameter of the materials forming the semiconductor layers may be divided into at least two kinds of values.

The diameter of the materials forming the complex semiconductor layers may be divided into at least two kinds of values.

Preferably, the semiconductor layers and the complex semiconductor layers may be alternately laminated.

Preferably, the semiconductor layers and the complex semiconductor layers may be alternately laminated to constitute a structure of at least three layers.

Preferably, the diameter of the materials forming the semiconductor layers may be about 10 nm to about 900 μm.

According to another exemplary embodiment of the present invention, there is provided a thermoelectric module including the thermoelectric elements.

The thermoelectric module may further include first and second electrodes facing each other. The thermoelectric elements may have P-type in one single mode and may be interposed between the first and second electrodes.

The thermoelectric module may further include first and second electrodes facing each other. The thermoelectric elements may have N-type in one single mode and may be interposed between the first and second electrodes.

The thermoelectric module may further include upper and lower substrates each having one surface on which a plurality of concave portions are formed. The thermoelectric elements may have P-type in one single mode and may be interposed between the upper and lower substrates.

The thermoelectric module may further include upper and lower substrates each having one surface on which a plurality of concave portions are formed. The thermoelectric elements may have N-type in one single mode and may be interposed between the upper and lower substrates.

The upper and lower substrates may be insulating substrates, and a conductive material may be coated on the surface of each of the upper and lower substrates which has the concave portions.

According to another exemplary embodiment of the present invention, there is provided a thermoelectric module, including: first and second electrodes facing each other; and a plurality of thermoelectric elements interposed between the first and second electrodes. The thermoelectric elements have any one of N-type and P-type in one single mode.

According to another exemplary embodiment of the present invention, there is provided a thermoelectric module, including: upper and lower substrates each having one surface on which a plurality of concave portions are formed; and thermoelectric elements each interposed between the upper and lower substrates by being partially inserted into the concave portions.

The upper and lower substrates may be insulating substrates, and a conductive material may be coated on the surface of each of the upper and lower substrates which has the concave portions.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a perspective view showing a structure of a general thermoelectric module;

FIG. 2 is a cross-sectional view showing a structure of a thermoelectric element according to a first exemplary embodiment of the present invention;

FIG. 3 is a cross-sectional view showing a structure of a thermoelectric element according to a second exemplary embodiment of the present invention;

FIG. 4 is a cross-sectional view showing a structure of a thermoelectric element according to a third exemplary embodiment of the present invention;

FIG. 5 is a cross-sectional view showing a structure of a thermoelectric element according to a fourth exemplary embodiment of the present invention;

FIG. 6 is a cross-sectional view showing a structure of a thermoelectric element according to a fifth exemplary embodiment of the present invention;

FIG. 7 is a cross-sectional view showing a structure of a thermoelectric element according to a sixth exemplary embodiment of the present invention;

FIG. 8 is a cross-sectional view showing a structure of a thermoelectric element according to a seventh exemplary embodiment of the present invention;

FIG. 9 is a perspective view showing a structure of a thermoelectric module according to a ninth exemplary embodiment of the present invention; and

FIG. 10 is a perspective view showing a structure of a thermoelectric module according to a tenth exemplary embodiment of the present invention.

### DESCRIPTION OF THE PREFERRED EMBODIMENTS

Various advantages and features of the present invention and methods accomplishing thereof will become apparent from the following description of embodiments with reference to the accompanying drawings. However, the present invention may be modified in many different forms and it should not be limited to the embodiments set forth herein. These embodiments may be provided so that this disclosure will be thorough and complete, and will fully convey the scope of the invention to those skilled in the art. Like reference numerals in the drawings denote like elements.

Terms used in the present specification are for explaining the embodiments rather than limiting the present invention. Unless explicitly described to the contrary, a singular form includes a plural form in the present specification. The word “comprise” and variations such as “comprises” or “comprising,” will be understood to imply the inclusion of stated constituents, steps, operations and/or elements but not the exclusion of any other constituents, steps, operations and/or elements.

Hereinafter, structures and operations of the present invention will be described in detail with reference to the accompanying drawings.

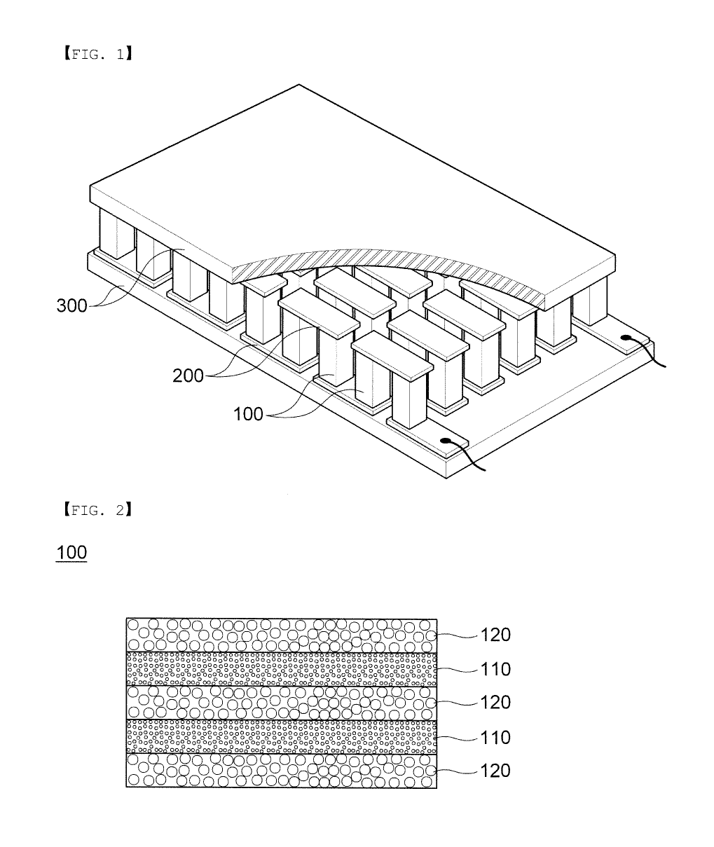

FIG. 1 shows a structure of a thermoelectric module, excluding a power supply unit. Generally, N-type and P-type semiconductors are used for a thermoelectric element 100. The module is formed by arranging the N-type and P-type semiconductors, which make plural pairs, on a plane and then connecting the semiconductors in series using metal electrodes. When current is applied to the module, carriers, that is, electrons (e−) and holes (h+), are generated in one side of the metal electrodes. The electrons and the holes flow to the n-type semiconductors and the p-type conductors, respectively, with transferring heat. These carriers are recombined in the opposite side of the metal electrodes.

Meanwhile, the thermoelectric figure of merit of the general thermoelectric element 100 is defined in Equation 1:

$$zT = \frac{{α}^{2} σ}{k} T \qquad [ Equation 1 ]$$

wherein, zT is thermoelectric figure of merit, α is Seebeck coefficient, σ is electrical conductivity, k is thermal conductivity, and T means temperature.

As represented in Equation 1, the thermal conductivity and the electrical conductivity have interrelation therebetween. In addition, electrons transfer heat and electricity together and phonons are media of transferring heat.

As shown in Equation 1, the electric conductivity and the thermal conductivity have an inverse relationship therebetween. Accordingly, in order to improve the thermoelectric figure of merit (zT), it is needed to increase the scattering of phonons while raising the electric conductivity by moving electrons appropriately from one end to the opposite end in the thermoelectric element 100.

The thermoelectric element 100 set forth in the present invention may have a layered structure in various manners. The scattering of phonons is increased at boundary parts between respective layers and throughout the entire of the thermoelectric element 100. As a result, the object of improving the thermoelectric figure of merit (zT) is accomplished.

Inventors of the present invention invented techniques of forming the thermoelectric element 100 by laminating layers having different physical properties, as a result of repeated studies on structures capable of improving the scattering of phonons as above.

That is, different physical properties are imparted to the layers of the thermoelectric element 100, by laminating plural semiconductor layers respectively formed of at least two kinds of thermoelectric semiconductor materials which are different from each other in at least one of diameter, density, and flatness, by using a sheet including a region formed of thermoelectric semiconductor materials and a region formed of metal materials, or by adding non-semiconductor materials in specific layers.

Hereafter, constitutions according to respective exemplary embodiments of the present invention will be described in detail with reference to the accompanying drawings.

### Example 1

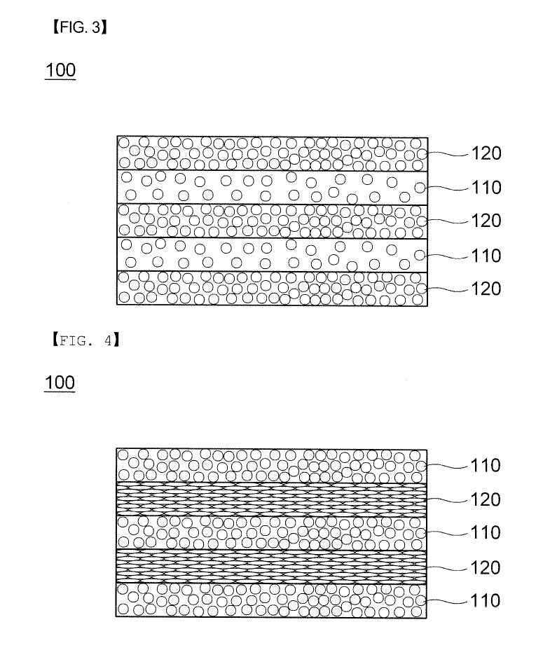

FIG. 2 shows a structure of a thermoelectric element 100 according to a first exemplary embodiment of the present invention.

Referring to FIG. 2, the thermoelectric element 100 may include: first semiconductor layers 110 formed of thermoelectric semiconductor materials; and second semiconductor layers 120 formed of semiconductor materials having a different diameter from the materials forming the first semiconductor layer 110.

At this time, the first semiconductor layers 110 and the second semiconductor layers 120 may be alternately laminated to maximize the difference of physical property at the interface between the layers. The first and second semiconductor layers may be laminated in three or more layers.

Also, it is preferable that the diameter of the materials forming the second semiconductor layers 120 is more than 5 times the diameter of the materials forming the first semiconductor layers 110, considering the interface effect due to the difference of physical property. If the difference of diameter between the materials forming the first semiconductor layers 110 and the materials forming the second semiconductor layers 120 is too small, the interface effect is not large such that the scattering of phonons is increased slightly, thereby making it impossible to accomplish the intended object.

The diameter of the materials forming the first semiconductor layers 110 is, preferably, about 10 nm to about 900 μm.

### Example 2

FIG. 3 shows a structure of a thermoelectric element 100 according to a second exemplary embodiment of the present invention.

Referring to FIG. 3, the thermoelectric element 100 may include: first semiconductor layers 110 formed of thermoelectric semiconductor materials; and second semiconductor layers 120 formed of semiconductor materials which make the second semiconductor layers 120 have a different density from the first semiconductor layers 110.

At this time, it is preferable that the density of the second semiconductor layers 120 is more than 1.5 times the density of the first semiconductor layers 110, in order to increase the scattering of phonons due to the interface effect between layers efficiently. If the difference of density is too small, the interface effect is not large such that the scattering of phonons is increased slightly, thereby making it impossible to accomplish the intended object.

Also, the first semiconductor layers 110 and the second semiconductor layers 120 may be alternately laminated to maximize the difference of physical property at the interface between the layers. The first and second semiconductor layers may be laminated in three or more layers.

### Example 3

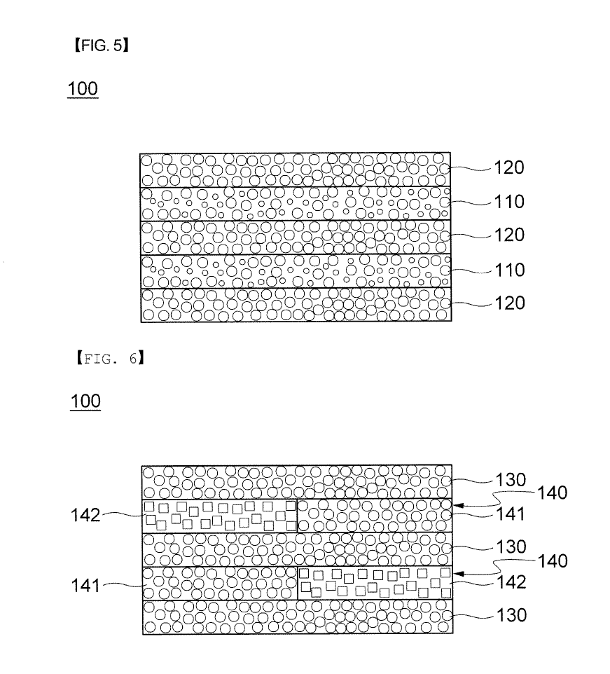

FIG. 4 shows a structure of a thermoelectric element 100 according to a third exemplary embodiment of the present invention.

Referring to FIG. 4, the thermoelectric element 100 may include: first semiconductor layers 110 formed of thermoelectric semiconductor materials; and second semiconductor layers 120 formed of thermoelectric semiconductor materials having a different flatness from the materials forming the first semiconductor layers 110.

The flatness may be numerically expressed by a ratio of major axis and minor axis of a particle.

In other words, if the minor axis/major axis ratio of the materials forming the first semiconductor layers 110 is different from the minor axis/major axis ratio of the materials forming the second semiconductor layers 120, the scattering of phonons can be increased at the interface between the two layers.

Herein, the rate of the minor axis/major axis ratio between the first semiconductor layers 110 and the second semiconductor layers 120 may be set in a range of 1:0.1 to 0.9, to maximize the scattering of phonons at the interface between the layers.

Also, the first semiconductor layers 110 and the second semiconductor layer 120 may be alternately laminated to maximize the difference of physical property at the interface between the layers. The first and second semiconductor layers may be laminated in three or more layers.

### Example 4

FIG. 5 shows a structure of a thermoelectric element according to a fourth exemplary embodiment of the present invention.

Referring to FIG. 5, the diameter of the materials forming the first semiconductor layers 110 or the diameter of the materials forming the second semiconductor layers 120 may be divided into at least two kinds of values to increase the scattering of phonons more.

In other words, if the first semiconductor layers 100 are composed of particles having different diameters and the second semiconductor layers 120 are composed of particles having the same diameter, the physical property is changed at the interface between the first semiconductor layers 110 and the second semiconductor layers 120, thereby increasing the scattering of phonons.

### Example 5

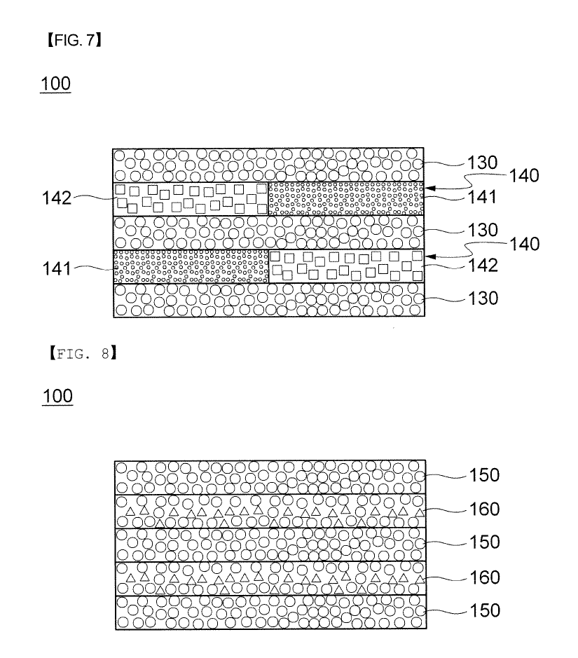

FIG. 6 shows a structure of a thermoelectric element 100 according to a fifth exemplary embodiment of the present invention.

Referring to FIG. 6, the thermoelectric element 100 may include: first thermoelectric layers 130 formed of thermoelectric semiconductor materials; and second thermoelectric layers 140 each formed by combining a region 141 formed of thermoelectric semiconductor materials and a region 142 formed of metal materials.

Herein, the materials suitable for use as the metal materials may be, but not limited to Cu, Ag, Ni, Pd, Al, B, and so on.

Preferably, the first thermoelectric layers 130 and the second thermoelectric layers 140 may be alternately laminated, and may be laminated in three or more layers.

Herein, if the region 141 formed of the thermoelectric semiconductor materials and the region 142 formed of the metal materials are positioned differently in each of the second thermoelectric layers 140 whenever the second thermoelectric layers 140 are disposed in different layer levels, the scattering of phonons can be more increased.

### Example 6

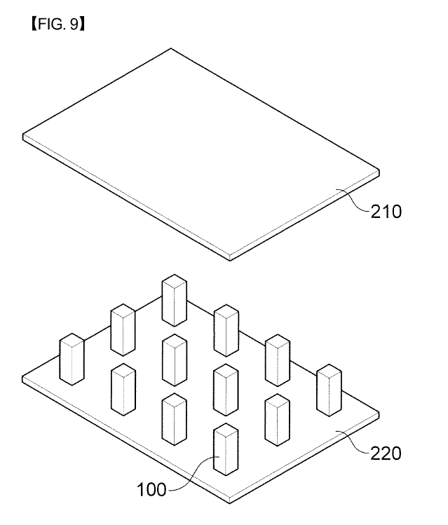

FIG. 7 shows a structure of a thermoelectric element 100 according to a sixth exemplary embodiment of the present invention.

Referring to FIG. 7, when the diameter of the thermoelectric semiconductor materials forming the first thermoelectric layers 130 is set differently from the diameter of the thermoelectric semiconductor materials forming the second thermoelectric layers 140, the scattering of phonons can be increased at the interface between the two layers.

In addition, as shown in FIG. 5 and the fourth exemplary embodiment, when the diameter of the materials forming the first thermoelectric layers 130 or the diameter of the materials forming the second thermoelectric layers 140 is divided into at least two kinds of values, the scattering of phonons can be more increased.

### Example 7

FIG. 8 shows a structure of a thermoelectric element 100 according to a seventh exemplary embodiment of the present invention.

Referring to FIG. 8, the thermoelectric element 100 may include: semiconductor layers 150 formed of thermoelectric semiconductor materials; and complex semiconductor layers 160 each formed by mixing semiconductor materials having a different diameter from the materials forming the semiconductor layers 150 and non-semiconductor materials.

The non-semiconductor materials contained in the complex semiconductor layers 160 are capable of inducing the scattering of phonons, and also, increasing the scattering of phonons at the interface between the semiconductor layers 150 and the complex semiconductor layers 160.

Herein, the diameter of the materials forming the semiconductor layers 150 may be divided into at least two kinds of values, and the diameter of the materials forming the complex semiconductor layers 160 may be divided into at least two kinds of values.

Preferably, the semiconductor layers 150 and the complex semiconductor layers 160 may be alternately laminated, and may be laminated in three or more layers.

Also, the diameter of the materials forming the semiconductor layers 150 is preferably about 10 nm to about 900 μm.

Also, the diameter of the materials forming the semiconductor layers or the complex semiconductor layers may be divided into at least two kinds of sizes.

### Example 8

Although not shown in the figures, a thermoelectric module according to an eighth exemplary embodiment of the present invention may include the thermoelectric elements 100 mentioned in the first to seventh exemplary embodiments.

### Example 9

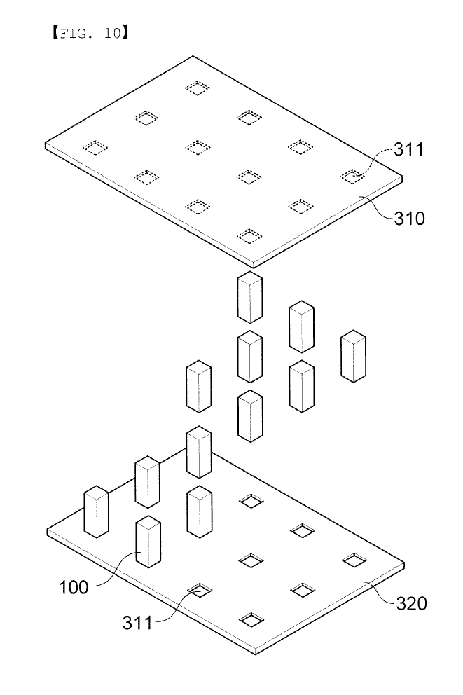

FIG. 9 shows a structure of a thermoelectric module according to a ninth exemplary embodiment of the present invention.

Referring to FIG. 9, the thermoelectric module according to the present invention may include a first electrode 210 and a second electrode 220 facing each other. Thermoelectric elements 100, which have P-type or N-type in one single mode, are interposed between the first electrode 210 and the second electrode 220.

The above constitution allows skipping the formation of complicate electrode patterns, compared with the existing serial type thermoelectric module, thereby improving the efficiency of manufacturing process. Also, since the thermoelectric performance is realized through normal thermoelectric elements 100 even though some of plural thermoelectric elements 100 have problems, the reliability is improved.

### Example 10

FIG. 10 shows a structure of a thermoelectric module according to a tenth exemplary embodiment of the present invention.

Referring to FIG. 10, the thermoelectric module according to the present invention may include an upper substrate 310 and a lower substrate 320 each having one surface on which a plurality of concave portions 311 are formed. The thermoelectric elements 100 may be interposed between the upper substrate 310 and the lower substrate 320.

Herein, the substrates 310 and 320 may be formed of conductive materials.

When the substrates 310 and 320 are formed of insulating materials, it is preferable that electrodes are formed in the concave portions 311 of the substrates 310 and 320 using conductive materials and the electrodes are connected electrically.

Also, a single mode of P-type or N-type thermoelectric elements 100 may be interposed between the conductive substrates or between the electrodes to improve the reliability of the thermoelectric module.

Also, the P-type and N-type thermoelectric elements 100 may be disposed in series. In this case, the electrodes are also arranged in series according to arrangement of the thermoelectric elements 100, such that the entire module is constituted in series.

The above constitution can improve the efficiency in an assembling process of connecting the thermoelectric elements 100 to the substrates or the electrodes, thereby reducing the manufacturing time and the manufacturing costs.

The thermoelectric semiconductor materials may be P-type semiconductor materials or N-type semiconductor materials.

In addition, the thermoelectric semiconductor materials may be composed of a mixture of Bi (bismuth) and Te (tellurium).

Also, the thermoelectric semiconductor materials may be composed of ZnₓSb_{y}, wherein x/y is 0.5 to 1.5, and especially, Zn₄Sb₃ (x=4, y=3) may be used.

Also, the thermoelectric semiconductor materials may be composed of CoₓSb_{y}, wherein x/y is 0.1 to 2.0, and especially, CoSb₃ (x=1, y=3) may be used.

As set forth above, the thermoelectric element and the thermoelectric module according to the present invention are capable of improving the thermoelectric figure of merit by inducing the scattering of phonons actively at the boundary portion between respective layers.

Also, according to the present invention, a plurality of single-type thermoelectric elements are connected in parallel to improve the reliability compared with the existing serial connection structure. The present invention is capable of simplifying the electrode structure and the assembling procedure to improve the efficiency of the manufacturing process of the thermoelectric module.

Also, the present invention is capable of improving the assembling process of the thermoelectric module using substrates having concave portions to reduce the manufacturing time and the manufacturing costs.

The present invention has been described in connection with what is presently considered to be practical exemplary embodiments. Although the exemplary embodiments of the present invention have been described, the present invention may be also used in various other combinations, modifications and environments. In other words, the present invention may be changed or modified within the range of concept of the invention disclosed in the specification, the range equivalent to the disclosure and/or the range of the technology or knowledge in the field to which the present invention pertains. The exemplary embodiments described above have been provided to explain the best state in carrying out the present invention. Therefore, they may be carried out in other states known to the field to which the present invention pertains in using other inventions such as the present invention and also be modified in various forms required in specific application fields and usages of the invention. Therefore, it is to be understood that the invention is not limited to the disclosed embodiments. It is to be understood that other embodiments are also included within the spirit and scope of the appended claims.

1. A thermoelectric element formed by laminating a plurality of semiconductor layers, wherein the semiconductor layers are, respectively, formed of at least two kinds of thermoelectric semiconductor materials which are different from each other in at least one of diameter, density and flatness.

2. A thermoelectric element, comprising:
first semiconductor layers formed of thermoelectric semiconductor materials; and
second semiconductor layers formed of thermoelectric semiconductor materials which are different from the materials forming the first semiconductor layers in at least one of diameter, density and flatness.

3. The thermoelectric element according to claim 2, wherein the first semiconductor layers and the second semiconductor layers are alternately laminated.

4. The thermoelectric element according to claim 2, wherein the first semiconductor layers and the second semiconductor layers are alternately laminated to constitute a structure of at least three layers.

5. The thermoelectric element according to claim 2, wherein the diameter of the materials forming the second semiconductor layers is more than 1.5 times the diameter of the materials forming the first semiconductor layers.

6. The thermoelectric element according to claim 2, wherein the diameter of the materials forming the first semiconductor layers is about 10 nm to about 900□.

7. The thermoelectric element according to claim 2, wherein the density of the second semiconductor layers is more than 1.5 times the density of the first semiconductor layers.

8. The thermoelectric element according to claim 2, wherein the rate between minor axis/major axis ratio of the materials forming the first semiconductor layers and minor axis/major axis ratio of the materials forming the second semiconductor layers is in the range of 1:0.1 to 0.9.

9. The thermoelectric element according to claim 2, wherein the diameter of the materials forming the first semiconductor layers is divided into at least two kinds of values.

10. The thermoelectric element according to claim 2, wherein the diameter of the materials forming the second semiconductor layers is divided into at least two kinds of values.

11. A thermoelectric element, comprising:
first thermoelectric layers formed of thermoelectric semiconductor materials; and
second thermoelectric layers each formed by combining a region formed of thermoelectric semiconductor materials and a region formed of metal materials.

12. The thermoelectric element according to claim 11, wherein the first thermoelectric layers and the second thermoelectric layers are alternately laminated.

13. The thermoelectric element according to claim 11, wherein the first thermoelectric layers and the second thermoelectric layers are alternately laminated to constitute a structure of at least three layers.

14. The thermoelectric element according to claim 11, wherein the region formed of the thermoelectric semiconductor materials and the region formed of the metal materials are positioned differently in each of the second thermoelectric layers whenever the second thermoelectric layers are disposed in different layer levels.

15. The thermoelectric element according to claim 11, wherein the diameter of the thermoelectric semiconductor materials forming the first thermoelectric layers is different from the diameter of the thermoelectric semiconductor materials forming the second thermoelectric layers.

16. The thermoelectric element according to claim 11, wherein the diameter of the materials forming the first semiconductor layers is divided into at least two kinds of values.

17. The thermoelectric element according to claim 10, wherein the diameter of the materials forming the second semiconductor layers is divided into at least two kinds of values.

18. A thermoelectric element, comprising:
semiconductor layers formed of thermoelectric semiconductor materials; and
complex semiconductor layers each formed by mixing thermoelectric semiconductor materials having a different diameter from the materials forming the semiconductor layers and non-semiconductor materials.

19. The thermoelectric element according to claim 18, wherein the diameter of the materials forming the semiconductor layers is divided into at least two kinds of values.

20. The thermoelectric element according to claim 18, wherein the diameter of the materials forming the complex semiconductor layers is divided into at least two kinds of values.

21. The thermoelectric element according to claim 18, wherein the semiconductor layers and the complex semiconductor layers are alternately laminated.

22. The thermoelectric element according to claim 18, wherein the semiconductor layers and the complex semiconductor layers are alternately laminated to constitute a structure of at least three layers.

23. The thermoelectric element according to claim 18, wherein the diameter of the materials forming the semiconductor layers is about 10 nm to about 900 um.

24. A thermoelectric module comprising thermoelectric elements according to claims 1, 2, 11 or 18.

25. The thermoelectric module according to claim 24, further comprising first and second electrodes facing each other, wherein the thermoelectric elements have P-type in one single mode and are interposed between the first and second electrodes.

26. The thermoelectric module according to claim 24, further comprising first and second electrodes facing each other, wherein the thermoelectric elements have N-type in one single mode and are interposed between the first and second electrodes.

27. The thermoelectric module according to claim 24, further comprising upper and lower substrates each having one surface on which a plurality of concave portions are formed, wherein the thermoelectric elements have P-type in one single mode and are interposed between the upper and lower substrates.

28. The thermoelectric module according to claim 25, further comprising upper and lower substrates each having one surface on which a plurality of concave portions are formed, wherein the thermoelectric elements have N-type in one single mode and are interposed between the upper and lower substrates.

29. The thermoelectric module according to claim 27 or 28, wherein each of the upper and lower substrates is an insulating substrate, and a conductive material is coated on the surface of each of the upper and lower substrates which has the concave portions.

30. A thermoelectric module, comprising:
first and second electrodes facing each other; and
a plurality of thermoelectric elements interposed between the first and second electrodes, the thermoelectric elements being any one of N-type and P-type in one single mode.

31. A thermoelectric module, comprising:
upper and lower substrates each having one surface on which a plurality of concave portions are formed; and
thermoelectric elements each interposed between the upper and lower substrates by being partially inserted into the concave portions.

32. The thermoelectric module according to claim 31, wherein each of the upper and lower substrates is an insulating substrate, and a conductive material is coated on the surface of each of the upper and lower substrates which has the concave portions.
